(19) United States
(12) Patent Application Publication
(10) Pub. No.: US 2025/0338393 A1
(43) Pub. Date: Oct. 30, 2025

(54) WIRING CIRCUIT BOARD AND METHOD OF PRODUCING THE WIRING CIRCUIT BOARD

(71) Applicant: NITTO DENKO CORPORATION, Osaka (JP)

(72) Inventors: Daisuke YAMAUCHI, Osaka (JP); Yuzuki AOKI, Osaka (JP); Shunya HASHIMOTO, Osaka (JP)

(73) Assignee: NITTO DENKO CORPORATION, Osaka (JP)

(21) Appl. No.: 19/187,624

(22) Filed: Apr. 23, 2025

(30) Foreign Application Priority Data
Apr. 26, 2024 (JP) 2024-073249

(51) Int. Cl. H05K 1/02; H05K 1/05; H05K 3/00; H05K 3/46

(52) U.S. Cl. CPC H05K 1/025; H05K 1/056; H05K 3/0017; H05K 3/4664; H05K 2201/09272; H05K 2201/09281; H05K 2201/10818

(57) ABSTRACT

A wiring circuit board includes a metal layer, a base insulating layer, and a circuit pattern. The circuit pattern includes a terminal and a wire connected to the terminal. The wire has a connecting portion connected to the terminal. The width of the terminal is larger than the width of the connecting portion. In the thickness direction, a distance between at least a portion of the terminal and the metal layer is longer than a distance between at least a portion of the connecting portion and the metal layer.

### CROSS-REFERENCE TO RELATED APPLICATION

The present application claims priority from Japanese Patent Application No. 2024-73249 filed on Apr. 26, 2024, the content of which is hereby incorporated by reference into this application.

### TECHNICAL FIELD

The present invention relates to a wiring circuit board and a method of producing the wiring circuit board.

### BACKGROUND ART

Conventionally, there has been known a wiring circuit board including a metal supporting board, an insulating layer, and a conductor layer. The conductor layer includes a terminal portion and a wiring portion connected to the terminal portion (for example, see Patent Document 1 below).

### CITATION LIST

### Patent Document

Patent Document 1: Japanese Unexamined Patent Publication No. 2022-111045

### SUMMARY OF THE INVENTION

### Problem to Be Solved by the Invention

According to the wiring circuit board described in Patent Document 1, the characteristic impedance of the terminal portion is adjusted by providing the metal supporting board with an opening portion facing the terminal portion.

In this regard, when the terminal portion is small or the metal supporting board is thick, it may be difficult to forming an opening in the metal supporting board.

The present invention provides a wiring circuit board capable of reducing the difference in impedance between the terminal and the wire without forming an opening in the metal layer, and a method of producing the wiring circuit board.

### Means for Solving The Problem

The present invention [1] includes a wiring circuit board including: a metal layer; a circuit pattern having a terminal and a wire connected to the terminal; and an insulating layer disposed between the metal layer and the circuit pattern in a thickness direction of the metal layer, wherein the wire has a connecting portion connected to the terminal, wherein a width of the terminal is larger than a width of the connecting portion, and wherein in the thickness direction, a distance between at least a portion of the terminal and the metal layer is longer than a distance between at least a portion of the connecting portion and the metal layer.

According to such a configuration, in the thickness direction, a distance between at least a portion of the terminal and the metal layer is longer than a distance between at least a portion of the connecting portion of the wire and the metal layer.

Therefore, the impedance of the terminal can be increased so as to be close to the impedance of the connecting portion.

As a result, the difference in impedance between the terminal and the wire can be reduced without forming an opening in the metal layer.

The present invention [2] includes the wiring circuit board described in the above-described [1], wherein a distance between a whole of the terminal and the metal layer is longer than the distance between at least the portion of the connecting portion and the metal layer.

According to such a configuration, the impedance of the whole of the terminal can be increased so as to be close to the impedance of the connecting portion.

Therefore, the difference in impedance between the terminal and the wire can further be reduced.

The present invention [3] includes the wiring circuit board described in the above-described [1], wherein the distance between the whole of the terminal and the metal layer is longer than a distance between a whole of the connecting portion and the metal layer.

According to such a configuration, the difference in impedance between the whole of the terminal and the whole of the connecting portion can be reduced.

Therefore, the difference in impedance between the terminal and the wiring can further be reduced.

The present invention [4] includes the wiring circuit board described in any one of the above-described [1] to [3], wherein the insulating layer includes: a first portion having a first thickness, and a second portion having a second thickness thicker than the first thickness, wherein at least the portion of the connecting portion is disposed on the first portion, and wherein at least the portion of the terminal is disposed on the second portion.

According to such a configuration, the distance between at least a portion of the terminal and the metal layer can be made longer than the distance between at least a portion of the connecting portion and the metal layer by providing the second portion of the insulating layer.

The present invention [5] includes the wiring circuit board described in the above-described [4], wherein the whole of the terminal is disposed on the second portion.

According to such a configuration, it is possible to increase the impedance of the whole of the terminal so as to be close to the impedance of the connecting portion.

Therefore, the difference in impedance between the terminal and the wire can further be reduced.

The present invention [6] includes the wiring circuit board described in the above-described [4] or [5], wherein the whole of the connecting portion is disposed on the first portion.

According to such a configuration, the impedance of the terminal can be increased so as to be close to the impedance of the whole of the connecting portion.

As a result, the difference in impedance between the terminal and the wire can further be reduced.

The present invention [7] includes the wiring circuit board described in any one of the above-described [4] to [6], wherein the second portion includes: a first layer unified with the first portion, and a second layer disposed on the first layer.

The present invention [8] includes the wiring circuit board described in any one of the above-described [4] to [6], wherein a whole of the second portion is unified with the first portion.

The present invention [9] includes the wiring circuit board described in any one of the above-described [1] to [8], wherein the metal layer includes: a first metal layer, and a second metal layer disposed between the first metal layer and the insulating layer in the thickness direction.

The invention [10] includes the wiring circuit board described in the above-described [9], wherein the second metal layer includes: a penetrating hole overlapping the terminal in the thickness direction.

The present invention [11] includes the wiring circuit board described in any one of the above-described [1] to [10], wherein the metal layer includes: a concave portion overlapping the terminal in the thickness direction, the concave portion being recessed in a direction away from the terminal in the thickness direction.

According to such a configuration, the distance between at least a portion of the terminal and the metal layer can be made longer than the distance between at least a portion of the connecting portion and the metal layer by providing the concave portion of the metal layer.

The present invention [12] includes a method of producing the wiring circuit board described in the above-described [7], the method including: a first insulating layer forming step of forming the first portion and the first layer of the second portion on the metal layer; a second insulating layer forming step of forming the second layer of the second portion on the first layer; and a patterning step of forming the circuit pattern on the insulating layer.

According to such a configuration, the first portion and the second portion can easily be formed in the insulating layer by carrying out the first insulating layer forming step and the second insulating layer forming step.

The present invention [13] includes a method of producing the wiring circuit board described in the above-described [8], the method including: an insulating layer forming step of forming the insulating layer on the metal layer; and a patterning step of forming the circuit pattern on the insulating layer, wherein in the insulating layer forming step, the first portion and the second portion are formed in the insulating layer by gradation exposure or etching.

According to such a configuration, the first portion and the second portion can easily be formed in the insulating layer by gradation exposure or etching.

The present invention [14] includes a method of producing the wiring circuit board described in the above-described [10], the method including: a metal layer forming step of forming the second metal layer having the penetrating hole on the first metal layer; an insulating layer forming step of forming the insulating layer on the second metal layer so that the insulating layer is filled in the penetrating hole; and a patterning step of forming the circuit pattern on the insulating layer.

According to such a configuration, by forming the second metal layer having the penetrating hole on the first metal layer, the metal layer having a concave portion can easily be formed.

The present invention [15] includes a method of producing the wiring circuit board described in the above-described [10], the method including: a metal layer forming step of forming the second metal layer on the first metal layer; a penetrating hole forming step of etching the second metal layer to form the penetrating hole in the second metal layer; an insulating layer forming step of forming the insulating layer on the second metal layer so that the insulating layer is filled in the penetrating hole; and a patterning step of forming the circuit pattern on the insulating layer.

According to such a configuration, the concave portion can easily be formed in the metal layer by etching the second metal layer.

The present invention [16] includes a method of producing the wiring circuit board described in the above-described [11], the method including: a concave portion forming step of etching the metal layer to form the concave portion in the metal layer; an insulating layer forming step of forming the insulating layer on the metal layer so that the insulating layer is filled in the concave portion; and a patterning step of forming the circuit pattern on the insulating layer.

According to such a configuration, the concave portion can easily be formed in the metal layer by etching the metal layer.

### Effects of the Invention

According to the wiring circuit board of the present invention, the difference in impedance between the terminal and the wire can be reduced without forming an opening in the metal layer.

According to the method for producing the wiring circuit board of the present invention, the above-described wiring circuit board can easily be produced.

### BRIEF DESCRIPTION OF THE DRAWINGS

FIG. 1A is a perspective view of a wiring circuit board of a first embodiment. FIG. 1B is a plan view of the wiring circuit board shown in FIG. 1A.

FIG. 2 is a cross-sectional view of the wiring circuit board shown in FIG. 1B, taken along line A-A.

FIGS. 3A to 3C are process diagrams showing a method of producing the wiring circuit board shown in FIG. 2, FIG. 3A shows a metal layer forming step, FIG. 3B shows a base insulating layer forming step, and FIG. 3C shows a patterning step.

FIG. 4 shows a wiring circuit board of a modified example (2) of the first embodiment.

FIG. 5A shows a first insulating layer forming step of the method of producing the wiring circuit board shown in FIG. 4, and FIG. 5B shows a second insulating layer forming step.

FIG. 6 shows a wiring circuit board of a modified example (3) of the first embodiment.

FIG. 7A is a plan view of a wiring circuit board of a modified example (4) of the first embodiment. FIG. 7B is a cross-sectional view of the wiring circuit board shown in FIG. 7A, taken along line B-B.

FIG. 8A is a plan view of a wiring circuit board of a modified example (5) of the first embodiment. FIG. 8B is a cross-sectional view of the wiring circuit board shown in FIG. 8A, taken along line C-C.

FIG. 9A is a plan view of a wiring circuit board of a modified example (6) of the first embodiment. FIG. 9B is a cross-sectional view of the wiring circuit board shown in FIG. 9A, taken along line D-D.

FIG. 10A is a perspective view of a wiring circuit board of a second embodiment. FIG. 10B is a plan view of the wiring circuit board shown in FIG. 10A.

FIG. 11 is a cross-sectional view of the wiring circuit board shown in FIG. 10B, taken along line E-E.

FIGS. 12A to 12D are process diagrams showing the method of producing the wiring circuit board shown in FIG. 11, FIG. 12A shows a metal layer forming step, FIG. 12B shows a penetrating hole forming step, FIG. 12C shows a base insulating layer forming step, and FIG. 12D shows a patterning step.

FIGS. 13A and 13B show a metal layer forming step of a modified example (1) of the second embodiment, FIG. 13A shows the step of forming the second metal layer while the portion where a penetrating hole is to be formed is covered with a plating resist, and FIG. 13B shows the step of releasing the plating resist.

FIG. 14 shows a wiring circuit board of a modified example (2) of the second embodiment.

FIGS. 15A to 15C are process diagrams showing the method of producing the wiring circuit board shown in FIG. 14, FIG. 15A shows a concave portion forming step, FIG. 15B shows a base insulating layer forming step, and FIG. 15C shows a patterning step.

FIG. 16A shows a wiring circuit board of a modified example (3) of the second embodiment. FIG. 16B shows a wiring circuit board of a modified example (4) of the second embodiment.

FIG. 17A is a plan view of a wiring circuit board of a modified example (5) of the second embodiment. FIG. 17B is a cross-sectional view of the wiring circuit board shown in

FIG. 17A, taken along line F-F.

### DESCRIPTION OF THE EMBODIMENT

### 1. First Embodiment

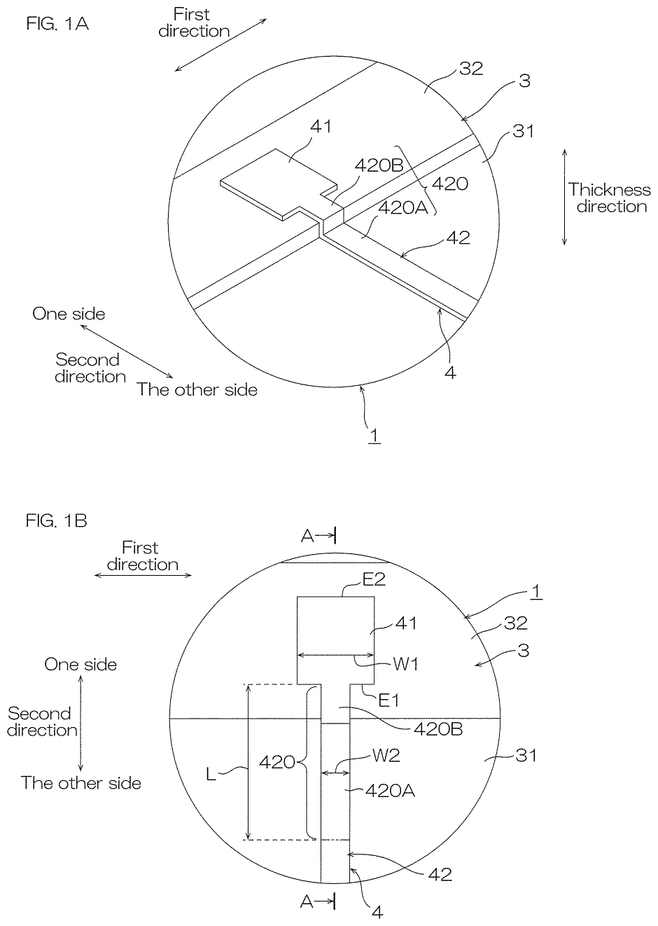

As shown in FIGS. 1A and 1B, a wiring circuit board 1 of a first embodiment extends in a first direction and a second direction. The second direction is perpendicular to the first direction. The shape of the wiring circuit board 1 is not limited to the first embodiment. The wiring circuit board 1 may be a flexible wiring circuit board or a suspension board with circuit.

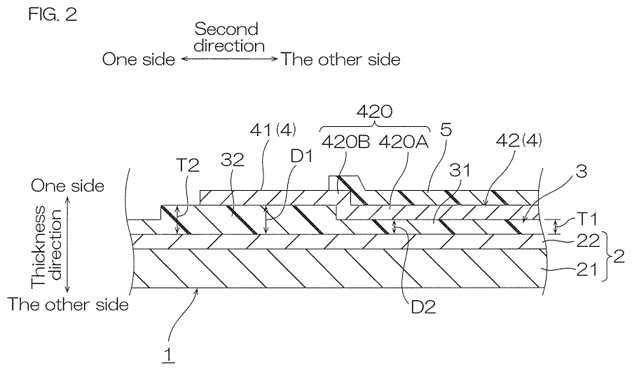

As shown in FIG. 2, the wiring circuit board 1 includes a metal layer 2, a base insulating layer 3 as an example of an insulating layer, a circuit pattern 4, and a cover insulating layer 5.

### (1) Metal Layer

The metal layer 2 supports the base insulating layer 3, the circuit pattern 4, and the cover insulating layer 5. The metal layer 2 may have a plurality of layers made of different metals. In the first embodiment, the metal layer 2 includes a first metal layer 21 and a second metal layer 22. In the first embodiment, the metal layer 2 may not have a second metal layer 22.

The first metal layer 21 is disposed away from the base insulating layer 3 in a thickness direction. The thickness direction is perpendicular to the first direction and the second direction. Examples of the material of the first metal layer 21 include stainless steel and a copper alloy.

The second metal layer 22 is disposed at one side of the first metal layer 21 in the thickness direction. The second metal layer 22 is disposed on a one-side surface of the first metal layer 21 in the thickness direction. The second metal layer 22 is disposed between the first metal layer 21 and the base insulating layer 3 in the thickness direction. The material of the second metal layer 22 may be the same as or different from the material of the first metal layer 21. Examples of the material of the second metal layer 22 include, for example, copper. The thickness of the second metal layer 22 may be smaller than the thickness of the first metal layer 21

### (2) Base Insulating Layer

The base insulating layer 3 is disposed at one side of the second metal layer 22 in the thickness direction. The base insulating layer 3 is disposed on a one-side surface of the second metal layer 22 in the thickness direction. The base insulating layer 3 is disposed between the second metal layer 22 and the circuit pattern 4 in the thickness direction. In other words, the base insulating layer 3 is disposed between the metal layer 2 and the circuit pattern 4 in the thickness direction. The base insulating layer 3 insulates the second metal layer 22 from the circuit pattern 4. The base insulating layer 3 is made of resin. Examples of the resin include polyimide, maleimide, epoxy resin, polybenzoxazole, and polyester. The base insulating layer 3 has a first portion 31 and a second portion 32. The first portion 31 has a first thickness T1. The second portion 32 is disposed at one side of the first portion 31 in the second direction. The second portion 32 is continuous with the first portion 31. The whole of the second portion 32 is unified with the first portion 31. In other words, the whole of the second portion 32 is made of the same material as that of the first portion 31, and is integral with the first portion 31. There is no interface between the first portion 31 and the second portion 32. The second portion 32 has a second thickness T2. The second thickness T2 is larger than the first thickness T1.

### (3) Circuit Pattern

The circuit pattern 4 is disposed at one side of the base insulating layer 3 in the thickness direction. The circuit pattern 4 is disposed on a one-side surface of the base insulating layer 3 in the thickness direction. The circuit pattern 4 is disposed on an opposite side to the metal layer 2 with respect to the base insulating layer 3 in the thickness direction. The circuit pattern 4 is made of metal. Examples of the metal include, for example, copper, silver, gold, iron, aluminum, chromium, and the alloys thereof. From the viewpoint of obtaining good electrical properties, copper is preferably used. The shape of the circuit pattern 4 is not limited.

As shown in FIGS. 1A and 1B, the circuit pattern 4 includes a terminal 41 and a wire 42.

At least a portion of the terminal 41 is disposed on the second portion 32 of the base insulating layer 3. In the first embodiment, the whole of the terminal 41 is disposed on the second portion 32. Therefore, in the first embodiment, the distance D1 between the terminal 41 and the metal layer 2 in the thickness direction (see FIG. 2) is substantially the same as the second thickness T2 (see FIG. 2) of the second portion 32 of the base insulating layer 3. The terminal 41 has a square land shape. Specifically, the terminal 41 extends in the first direction and the second direction. The terminal 41 has a substantially rectangular shape. The wiring circuit board 1 may include a plurality of terminals 41. When the wiring circuit board 1 includes a plurality of terminals 41, the plurality of terminals 41 are arranged, for example, in the first direction.

The wire 42 is connected to the terminal 41. Specifically, the wire 42 has a connecting portion 420 connected to the terminal 41.

The connecting portion 420 is continuous with the other end portion of the terminal 41 in the second direction. In the first embodiment, the connecting portion 420 extends in the second direction. The direction in which the connecting portion 420 extends is not limited. The connecting portion 420 may extend from the other end portion of the terminal 41 in the second direction and then be curved toward the first direction.

The width W1 of the terminal 41 differs from the width W2 of the connecting portion 420. Specifically, the width W1 of the terminal 41 is larger than the width W2 of the connecting portion 420.

The width W1 of the terminal 41 is the length of the terminal 41 in the first direction. In other words, the terminal 41 has an end portion E1 to which the connecting portion 420 is connected, and an end portion E2 which is disposed on the opposite side to the connecting portion 420 with respect to the end portion E1. The width W1 of the terminal 41 is the length of the terminal 41 in a direction perpendicular to the direction from the end portion E1 toward the end portion E2.

The width W2 of the connecting portion 420 is the length of the connecting portion 420 in the first direction. In other words, the width W2 of the connecting portion 420 is the length of the connecting portion 420 in the direction perpendicular to the direction in which the connecting portion 420 extends.

The length L of the connecting portion 420 is 1000 μm. In other words, the “connecting portion 420” is a portion of the wire 42 that is from the terminal 41 to a part that is 1000 μm away from the terminal 41.

At least a portion 420A of the connecting portion 420 is disposed on the first portion 31 of the base insulating layer 3. In the first embodiment, an end portion 420B of the connecting portion 420 is disposed on the second portion 32 together with the terminal 41. The end portion 420B is disposed between the portion 420A and the terminal 41. The lower limit of the length of the end portion 420B is not limited. The length of the end portion 420B may be zero. That is, the whole of the connecting portion 420 may be disposed on the first portion 31.

In the first embodiment, as shown in FIG. 2, the distance D2 between the portion 420A and the metal layer 2 in the thickness direction is substantially the same as the first thickness T1 of the first portion 31 of the base insulating layer 3. Therefore, the distance D1 between the whole of the terminal 41 and the metal layer 2 in the thickness direction is longer than the distance D2 between at least the portion 420A of the connecting portion 420 and the metal layer 2. The difference between the distance D1 and the distance D2 is, for example, 1 μm to 30 μm, preferably 5 μm to 20 μm.

That is, the terminal 41 that is wider than the connecting portion 420 is disposed away from the metal layer 2 as compared with at least the portion 420A of the connecting portion 420.

Therefore, the impedance of the terminal 41 can be made close to the impedance of the connecting portion 420.

As a result, an increase in return loss due to discontinuity in impedance between the terminal 41 and the connecting portion 420 can be suppressed.

### (4) Cover Insulating Layer

The cover insulating layer 5 covers the wire 42. The cover insulating layer 5 is disposed on the base insulating layer 3 in the thickness direction. The cover insulating layer 5 does not cover the terminal 41. The cover insulating layer 5 is made of resin. Examples of the resin include polyimide, maleimide, epoxy resin, polybenzoxazole, and polyester.

### 2. Method of Producing Wiring Circuit Board of First Embodiment

Next, a method of producing the wiring circuit board 1 of the first embodiment is described.

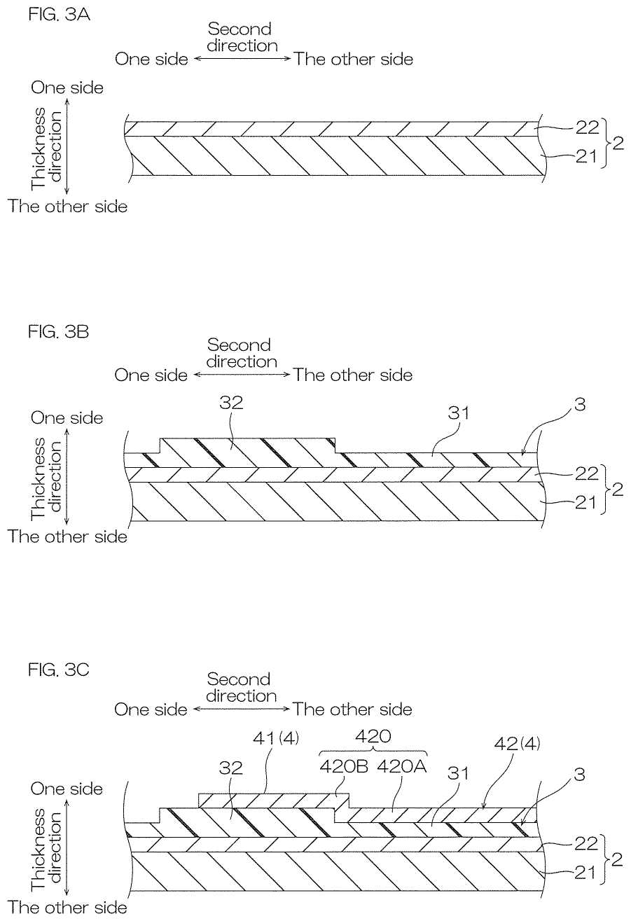

A method of producing the wiring circuit board 1 includes a metal layer forming step (see FIG. 3A), a base insulating layer forming step (see FIG. 3B), a patterning step (see FIG. 3C), and a cover insulating layer forming step (see FIG. 2).

### (1) Metal Layer Forming Step

In the metal layer forming step, as shown in FIG. 3A, a second metal layer 22 is formed on a one-side surface of a first metal layer 21 in the thickness direction, for example, by electrolytic plating.

### (2) Base Insulating Layer Forming Step

Next, as shown in FIG. 3B, in the base insulating layer forming step, the base insulating layer 3 is formed on the metal layer 2. In the first embodiment, the base insulating layer 3 is formed on the second metal layer 22.

In the base insulating layer forming step, a first portion 31 and a second portion 32 are formed in the base insulating layer 3 by gradation exposure.

Specifically, first, a solution (varnish) of a photosensitive resin is applied onto the metal layer 2 and dried to form a coating film of the photosensitive resin.

Next, the coating film of the photosensitive resin is subjected to gradation exposure using a photomask having a light-shielding portion, a fully-transmissive portion, and a semi-transmissive portion. The light-shielding portion faces a portion of the coating film of the photosensitive resin where the base insulating layer 3 is not formed. The semi-transmissive portion faces a portion of the coating film of the photosensitive resin where a first portion 31 is to be formed. The fully-transmissive portion faces a portion of the coating film of the photosensitive resin where a second portion 32 is to be formed.

Next, the coating film exposed to light is developed. The portion of the coating film that faces the semi-transmissive portion is developed thinner than the portion that faces the fully-transmissive portion. In this manner, the base insulating layer 3 is formed into the above-described pattern on the metal layer 2.

### (3) Patterning Step

Next, as shown in FIG. 3C, in the patterning step, a circuit pattern 4 is formed on the base insulating layer 3.

In the patterning step, first, a seed layer is formed on the one-side surface of the base insulating layer 3 and a one-side surface of the second metal layer 22 in the thickness direction. The seed layer is formed, for example, by sputtering. Examples of the material of the seed layer include, for example, chromium, copper, nickel, titanium, and the alloys thereof.

Next, a plating resist is attached to the one-side surface of the second metal layer 22 in the thickness direction. The plating resist covers the base insulating layer 3.

Next, the plating resist is exposed to light and developed. Then, the plating resist in the portion where a circuit pattern 4 is to be formed is removed, and the seed layer is exposed in the portion where a circuit pattern 4 is to be formed. On the other hand, the plating resist in the portion where a circuit pattern 4 is not formed remains.

Next, the circuit pattern 4 is formed on the exposed seed layer by electrolytic plating. After the electrolytic plating is completed, the plating resist is released, and the seed layer exposed by the release of the plating resist is removed by etching.

### (4) Cover Insulating Layer Forming Step

Next, as shown in FIG. 2, in the cover insulating layer forming step, a cover insulating layer 5 is formed on the base insulating layer 3.

Specifically, in the cover insulating layer forming step, first, a solution (varnish) of a photosensitive resin is applied onto the circuit pattern 4, the base insulating layer 3, and the second metal layer 22 and dried to form a coating film of the photosensitive resin.

Next, the coating film of the photosensitive resin is exposed to light and developed. In this manner, a cover insulating layer 5 is formed on the base insulating layer 3.

### 3. Operations and Effects

(1) According to the wiring circuit board 1 of the first embodiment, as shown in FIG. 2, the distance D1 between the whole of the terminal 41 and the metal layer 2 in the thickness direction is longer than the distance D2 between the portion 420A disposed on the first portion 31 of the base insulating layer 3 in the connecting portion 420 of the wire 42 and the metal layer 2.

Therefore, the impedance of the whole of the terminal 41 can be increased so as to be close to the impedance of the connecting portion 420.

As a result, the difference in impedance between the terminal 41 and the wire 42 can be reduced without forming an opening in the metal layer 2.

(2) According to the wiring circuit board 1 of the first embodiment, as shown in FIG. 2, the base insulating layer 3 includes the first portion 31 having the first thickness T1 and the second portion 32 having the second thickness T2 larger than the first thickness T1. A portion 420A of the connecting portion 420 is disposed on the first portion 31. The whole of the terminal 41 is disposed on the second portion 32.

Therefore, the distance D1 between the whole of the terminal 41 and the metal layer 2 can be made longer than the distance D2 between the portion 420A of the connecting portion 420 and the metal layer 2 by providing the second portion 32 of the base insulating layer 3.

(3) According to the method of producing the wiring circuit board 1 of the first embodiment, as shown in FIG. 3B, the first portion 31 and the second portion 32 are formed in the base insulating layer 3 by gradation exposure in the base insulating layer forming step.

Therefore, the first portion 31 and the second portion 32 can easily be formed in the base insulating layer 3.

### 4. Modified Examples of First Embodiment

Next, the modified examples of the first embodiment are described. In the modified examples, the same members as the first embodiment are given the same numerical references and the descriptions thereof are omitted.

(1) In the base insulating layer forming step shown in FIG. 3B, the first portion 31 and the second portion 32 may be formed in the base insulating layer 3 by etching.

Specifically, first, a solution (varnish) of a photosensitive resin is applied onto the metal layer 2 and dried to form a coating film of the photosensitive resin.

Next, the coating film of the photosensitive resin is exposed to light and developed. In this manner, the base insulating layer 3 with the second thickness T2 is formed on the metal layer 2.

Next, the first portion 31 of the base insulating layer 3 is etched to make the thickness of the first portion 31 thinner than that of the second portion 32.

Also in this modified example, the first portion 31 and the second portion 32 can easily be formed in the base insulating layer 3.

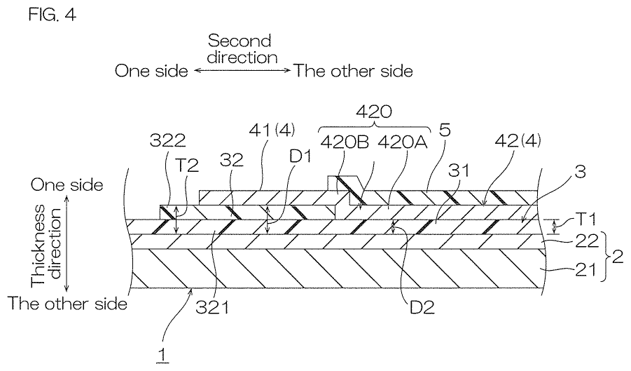

(2) As shown in FIG. 4, the second portion 32 may have a first layer 321 and a second layer 322 disposed on the first layer 321.

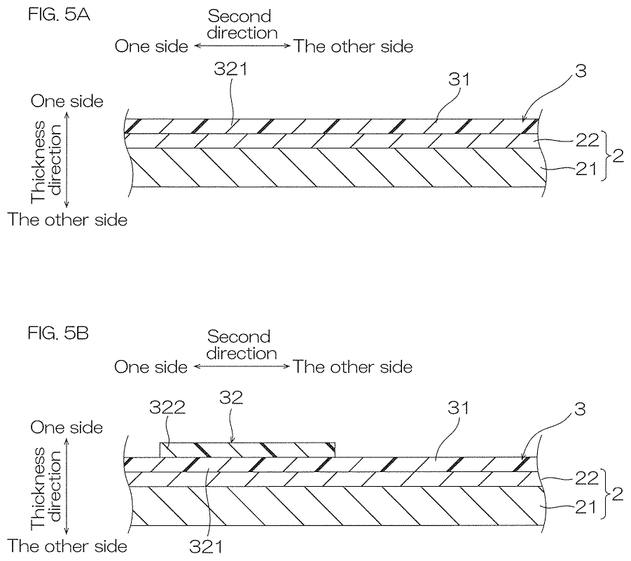

In this case, the method of producing the wiring circuit board 1 includes a first insulating layer forming step (see FIG. SA) and a second insulating layer forming step (see FIG. 5B) in place of the above-described base insulating layer forming step (see FIG. 3B). That is, in this modified example, the method of producing the wiring circuit board 1 includes the metal layer forming step (see FIG. 3A), the first insulating layer forming step (see FIG. 5A), the second insulating layer forming step (see FIG. 5B), the patterning step (see FIG. 3C), and the covering insulating layer forming step (see FIG. 2).

As shown in FIG. 5A, in the first insulating layer forming step, a first portion 31 and a first layer 321 of a second portion 32 are formed on the metal layer 2.

Specifically, in the first insulating layer forming step, a solution (varnish) of a photosensitive resin is applied onto the metal layer 2 and dried to form a coating film of the photosensitive resin.

Next, the coating film of the photosensitive resin is exposed to light and developed. In this manner, a first portion 31 and a first layer 321 of a second portion 32 are formed with the first thickness T1 (see FIG. 4) on the metal layer 2. The first layer 321 of the second portion 32 is unified with the first portion 31. In other words, the first layer 321 of the second portion 32 is made of the same material as that of the first portion 31, and is integral with the first portion 31. There is no interface between the first portion 31 and the first layer 321.

Next, as shown in FIG. 5B, in the second insulating layer forming step, a second layer 322 of the second portion 32 is formed on the first layer 321.

Specifically, in the second insulating layer forming step, a solution (varnish) of a photosensitive resin is applied onto the first layer 321 and dried to form a coating film of the photosensitive resin. The coating film of the photosensitive resin may also be formed on the first portion 31 and the metal layer 2.

Next, the coating film of the photosensitive resin is exposed to light and developed. In this manner, a second layer 322 is formed on the first layer 321. In this modified example, the total sum of the thickness of the first layer 321 and the thickness of the second layer 322 is the second thickness T2 (see FIG. 4). There is an interface present between the first layer 321 and the second layer 322. That is, the second layer 322 of the second portion 32 is not unified with the first portion 31 and the first layer 321.

Also in this modified example, as shown in FIG. 4, in the thickness direction, the distance D1 between the whole of the terminal 41 and the metal layer 2 is longer than the distance D2 between the portion 420A disposed on the first portion 31 of the base-insulating layer 3 in the connecting portion 420 of the wire 42 and the metal layer 2.

Therefore, the impedance of the whole of the terminal 41 can be increased so as to be close to the impedance of the connecting portion 420.

As a result, the difference in impedance between the terminal 41 and the wire 42 can be reduced without forming an opening in the metal layer 2.

Further, as shown in FIGS. SA and SB, the first portion 31 and the second portion 32 can easily be formed in the base insulating layer 3 by carrying out the first insulating layer forming step and the second insulating layer forming step.

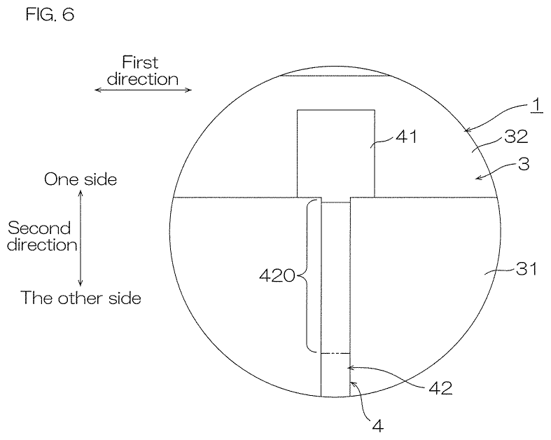

(3) As shown in FIG. 6, the whole of the connecting portion 420 may be disposed on the first portion 31. In this case, the distance D1 between the whole of the terminal 41 and the metal layer 2 is longer than the distance D2 between the whole of the connecting portion 420 and the metal layer 2.

Therefore, the difference in impedance between the whole of the terminal 41 and the whole of the connecting portion 420 can be reduced.

As a result, the difference in impedance between the terminal 41 and the wire 42 can further be reduced.

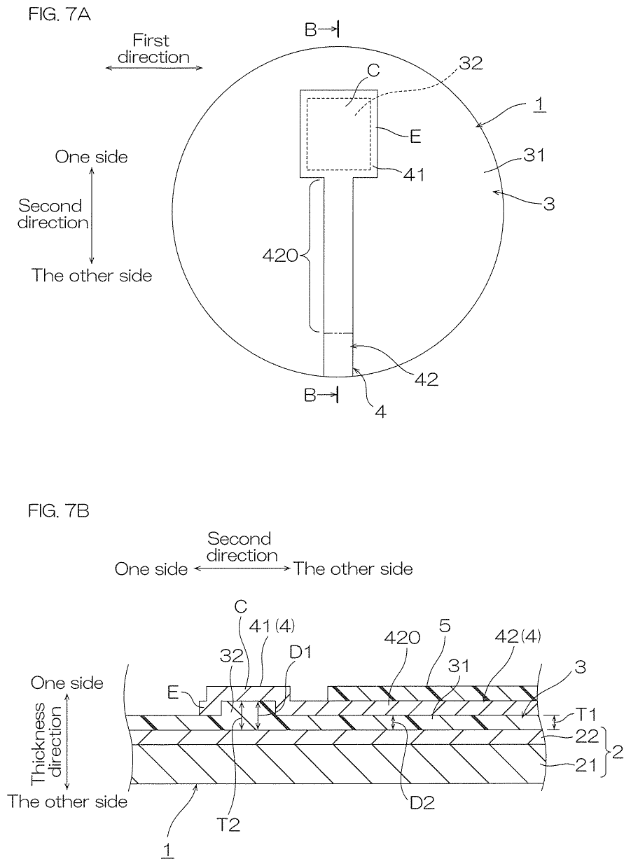

(4) A portion of the terminal 41 may be disposed on the first portion 31 together with the connecting portion 420. Specifically, as shown in FIGS. 7A and 7B, the second portion 32 may be smaller than the terminal 41, and a peripheral edge portion E of the terminal 41 may be disposed on the first portion 31 together with the connecting portion 420. That is, one end portion of the terminal 41 in the first direction, the other end portion of the terminal 41 in the first direction, one end portion of the terminal 41 in the second direction, and the other end portion of the terminal 41 in the second direction may be disposed on the first portion 31. A central portion C of the terminal 41 is disposed on the second portion 32. The central portion C is a central portion of the terminal 41 in the first direction and a central portion of the terminal 41 in the second direction.

In this case, the area of the second portion 32 is, for example, 30% or more, preferably 50% or more, and more preferably 80% or more of the area of the terminal 41.

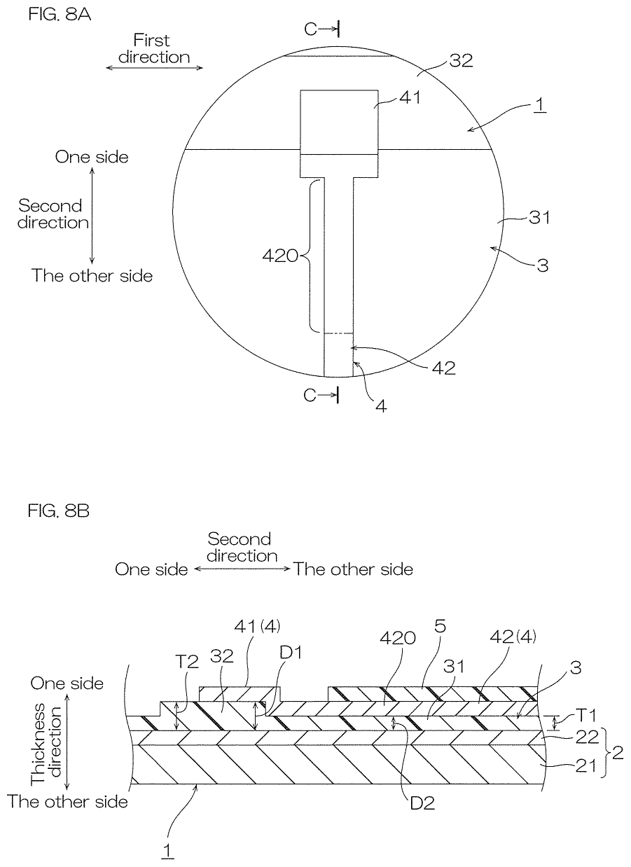

(5) As shown in FIGS. 8A and 8B, only the other end portion of the terminal 41 in the second direction may be disposed on the first portion 31 together with the connecting portion 420

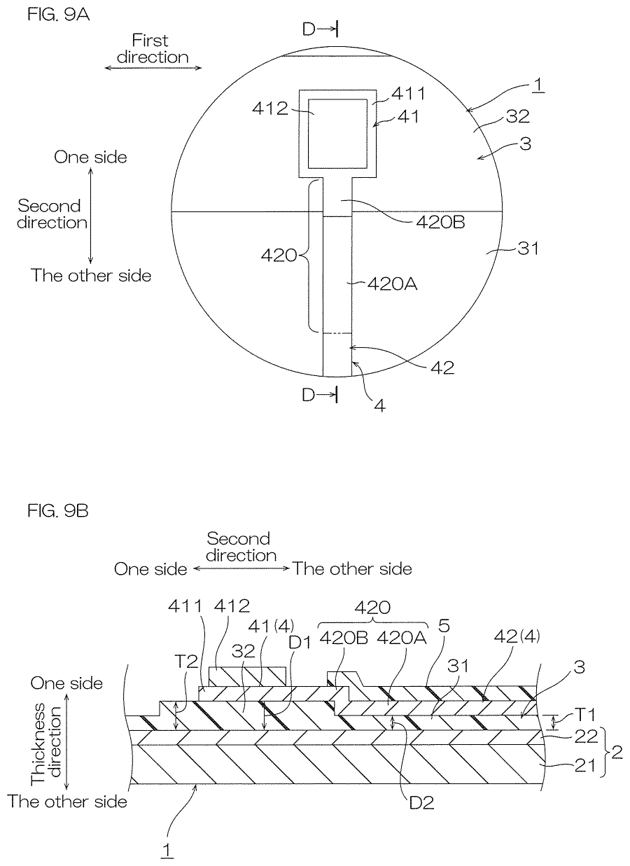

(6) The terminal 41 may have a plurality of conductor layers. Specifically, as shown in FIGS. 9A and 9B, the terminal 41 may include a first conductor layer 411 and a second conductor layer 412. At least a portion of the first conductor layer 411 is disposed on the second portion 32 of the base insulating layer 3. The connecting portion 420 is connected to the first conductor layer 411. In this modified example, the whole of the first conductor layer 411 is disposed on the second portion 32 of the base insulating layer 3. In the same manner as the modified examples (4) and (5) described above, a portion of the first conductor layer 411 may be disposed on the first portion 31 together with the connecting portion 420. Examples of the material of the first conductor layer 411 include, for example, the same materials as those of the circuit pattern 4 described above. The secondary conductor layer 412 is disposed on the first conductor layer 411. The second conductor layer 412 may be made of the same material as that of the first conductor layer 411. The second conductor layer 412 may be made of a material (e.g., solder) different from that of the first conductor layer 411.

(7) In the modified examples (1) to (6) described above, in the same manner as the first embodiment described above, the difference in impedance between the terminal 41 and the wire 42 can be reduced without forming an opening in the metal layer 2.

### 5. Wiring Circuit Board of Second Embodiment

Next, a wiring circuit board 10 of a second embodiment is described. In the second embodiment, the same members as the first embodiment are given the same numerical references and the descriptions thereof are omitted.

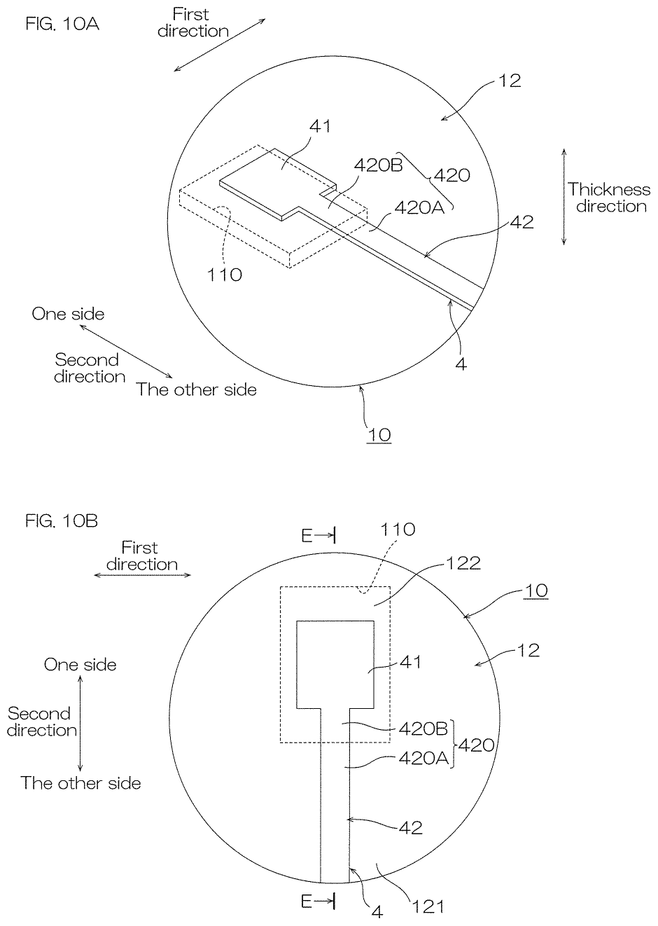

As shown in FIGS. 10A and 10B, the wiring circuit board 10 of the second embodiment extends in the first direction and the second direction in the same manner as the wiring circuit board 1 of the first embodiment.

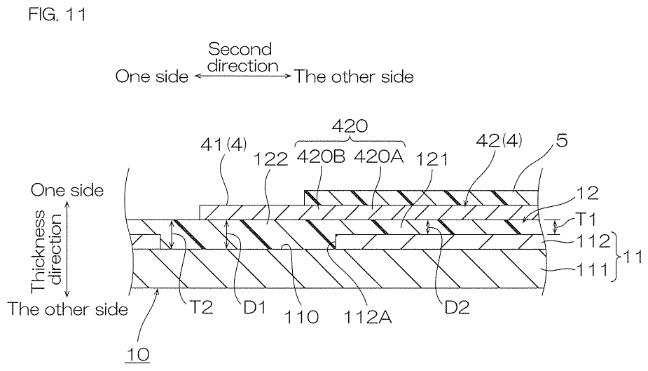

As shown in FIG. 11, the wiring circuit board 10 of the second embodiment includes a metal layer 11, a base insulating layer 12, a circuit pattern 4, and a cover insulating layer 5.

### (1) Metal Layer

The metal layer 11 supports the base insulating layer 12, the circuit pattern 4, and the cover insulating layer 5. The metal layer 11 has a concave portion 110.

As shown in FIG. 10B, the concave portion 110 overlaps a terminal 41 in the thickness direction. In the second embodiment, the concave portion 110 is larger than the terminal 41 in the first direction and the second direction. In the second embodiment, the whole of the terminal 41 overlap the concave portion 110. Further, an end portion 420B of the connecting portion 420 overlaps the concave portion 110 together with the terminal 41. A portion 420A of the connecting portion 420 does not overlap the concave portion 110.

As shown in FIG. 11, the concave portion 110 is recessed in a direction away from the terminal 41 in the thickness direction. In this manner, in the thickness direction, the distance D1 between the whole of the terminal 41 and the metal layer 11 is longer than the distance D2 between the portion 420A of the connecting portion 420 and the metal layer 11.

That is, also in the second embodiment, the terminal 41 that is wider than the connecting portion 420 is disposed away from the metal layer 11 as compared with the portion 420A of the connecting portion 420.

Therefore, the impedance of the terminal 41 can be made close to the impedance of the connecting portion 420.

As a result, an increase in return loss due to discontinuity in impedance between the terminal 41 and the connecting portion 420 can be suppressed.

The metal layer 11 may have a plurality of layers made of different metals. In the second embodiment, the metal layer 11 includes a first metal layer 111 and a second metal layer 112.

The first metal layer 111 is made of the same material as that of the first metal layer 21 of the first embodiment.

The second metal layer 112 is disposed at one side of the first metal layer 111 in the thickness direction. The second metal layer 112 is disposed on a one-side surface of the first metal layer 111 in the thickness direction. The second metal layer 112 is disposed between the first metal layer 111 and the base insulating layer 12 in the thickness direction. The second metal layer 112 is made of the same material as that of the first metal layer 111 of the first embodiment. The concave portion 110 may penetrate the second metal layer 112. In other words, the second metal layer 112 may have a penetrating hole 112A. The penetrating hole 112A overlaps the terminal 41 in the thickness direction.

### (2) Base Insulating Layer

The base insulating layer 12 is disposed at one side of the metal layer 11 in the thickness direction. The base insulating layer 12 is disposed on a one-side surface of the metal layer 11 in the thickness direction. The base insulating layer 12 insulates the metal layer 11 from the circuit pattern 4. The base insulating layer 12 is made of the same resin as that of the base insulating layer 3 of the first embodiment. A portion of the base insulating layer 12 is disposed in the concave portion 110 of the metal layer 11. When the second metal layer 112 has the penetrating hole 112A, a portion of the base insulating layer 12 is disposed in the penetrating hole 112A of the second metal layer 112. Specifically, the base insulating layer 12 includes a first portion 121 and a second portion 122.

The first portion 121 is disposed between the second metal layer 112 and the circuit pattern 4 in the thickness direction. The first portion 121 has a first thickness T1.

The second portion 122 is disposed in the concave portion 110 of the metal layer 11. The second portion 122 is disposed between the first metal layer 111 and the circuit pattern 4 in the thickness direction. The second portion 122 insulates the first metal layer 111 from the circuit pattern 4. The second portion 122 is continuous with the first portion 121. The whole of the second portion 122 is unified with the first portion 121. In other words, the whole of the second portion 122 is made of the same material as that of the first portion 121, and integral with the first portion 121. There is no interface between the first portion 121 and the second portion 122. The second portion 122 has a second thickness T2. The second thickness T2 is larger than the first thickness T1.

In the second embodiment, the whole of the terminal 41 is disposed on the second portion 122. The portion 420A of the connecting portion 420 is disposed on the first portion 121. The end portion 420B of the connecting portion 420 is disposed on the second portion 122 together with the terminal 41.

The distance D1 between the terminal 41 and the metal layer 11 in the thickness direction is substantially the same as the second thickness T2 of the second portion 122 of the base insulating layer 12, and the distance D2 between the portion 420A and the metal layer 11 in the thickness direction is substantially the same as the first thickness T1 of the first portion 121 of the base insulating layer 12.

Therefore, in the second embodiment, in the same manner as the first embodiment, in the thickness direction, the distance D1 between the whole of the terminal 41 and the metal layer 11 is longer than the distance D2 between the portion 420A of the connecting portion 420 and the metal layer 11. In other words, the terminal 41 that is wider than the connecting portion 420 is disposed away from the metal layer 11 as compared with the portion 420A of the connecting portion 420.

Therefore, the impedance of the terminal 41 can be made close to the impedance of the connecting portion 420.

As a result, it is possible to reduce the return loss due to discontinuity in impedance between the terminal 41 and the connecting portion 420.

### 6. Method of Producing Wiring Circuit Board of Second Embodiment

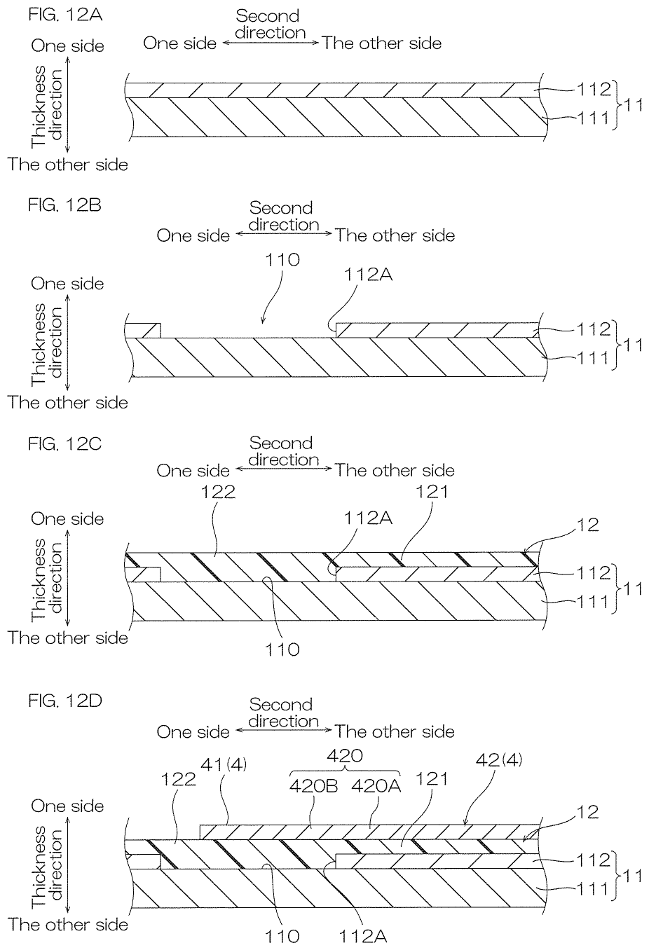

A method of producing the wiring circuit board 10 includes a metal layer forming step (see FIG. 12A), a penetrating hole forming step (see FIG. 12B) as an example of a concave portion forming step, a base insulating layer forming step (see FIG. 12C), a patterning step (see FIG. 12D), and a cover insulating layer forming step (see FIG. 11).

### (1) Metal Layer Forming Step

In the metal layer forming step, as shown in FIG. 12A, a second metal layer 112 is formed on a one-side surface of the first metal layer 111 in the thickness direction in the same manner as in the metal layer forming step of the first embodiment.

### (2) Penetrating Hole Forming Step

Next, as shown in FIG. 12B, in the penetrating hole forming step, the second metal layer 112 is etched to form a penetrating hole 112A in the second metal layer 112. In other words, the second metal layer 112 of the metal layer 11 is etched to form a concave portion 110 in the metal layer 11.

### (3) Base Insulating Layer Forming Step

Next, as shown in FIG. 12C, in the base insulating layer forming step, a base insulating layer 12 is formed on the metal layer 11 so that the base insulating layer 12 is filled in the penetrating hole 112A (i.e., the concave portion 110).

Specifically, first, a solution (varnish) of a photosensitive resin is applied onto the metal layer 11. At this time, the solution of the photosensitive resin is applied to a one-side surface of the second metal layer 112 and filled in the penetrating hole 112A (concave portion 110).

Next, the solution of the photosensitive resin is dried. Then, a coating film of the photosensitive resin is formed on a one-side surface of the second metal layer 112 and in the penetrating hole 112A (concave portion 110).

Next, the coating film of the photosensitive resin is exposed to light and developed. In this manner, the base insulating layer 12 is formed on the metal layer 11. The first portion 121 of the base insulating layer 12 is disposed on a one-side surface of the second metal layer 112. The second portion 122 of the base insulating layer 12 is filled in the penetrating hole 112A (concave portion 110).

### (4) Patterning Step

Next, as shown in FIG. 12D, in the patterning step, a circuit pattern 4 is formed on the base insulating layer 12 in the same manner as in the patterning step of the first embodiment.

### (5) Cover Insulating Layer Forming Step

Next, as shown in FIG. 11, in the cover insulating layer forming step, a cover insulating layer 5 is formed on the base insulating layer 12 in the same manner as in the cover insulating layer forming step of the first embodiment.

### 7. Operations and Effects

(1) According to the wiring circuit board 10 of the second embodiment, as shown in FIG. 11, the metal layer 11 has the concave portion 110 recessed in a direction away from the terminal 41 in the thickness direction. As shown in FIG. 10B, the concave portion 110 overlaps the whole of the terminal 41 in the thickness direction.

Therefore, as shown in FIG. 11, the distance D1 between the whole of the terminal 41 and the metal layer 11 can be made longer than the distance D2 between the portion 420A of the connecting portion 420 and the metal layer 11 by providing the concave portion 110 of the metal layer 11.

In this manner, the impedance of the whole of the terminal 41 can be increased so as to be close to the impedance of the connecting portion 420.

As a result, the difference in impedance between the terminal 41 and the wire 42 can be reduced without forming an opening in the metal layer 11.

(2) According to the wiring circuit board 10 of the second embodiment, as shown in FIG. 12B, in the penetrating hole forming step, the second metal layer 112 is etched to form the penetrating hole 112A in the second metal layer 112.

Therefore, a concave portion 110 can easily be formed in the metal layer 11 by carrying out a simple step of etching the second metal layer 112.

### 8. Modified Examples of Second Embodiment

Next, modified examples of the second embodiment are described. In the modified examples, the same members as the second embodiment are given the same numerical references and the descriptions thereof are omitted.

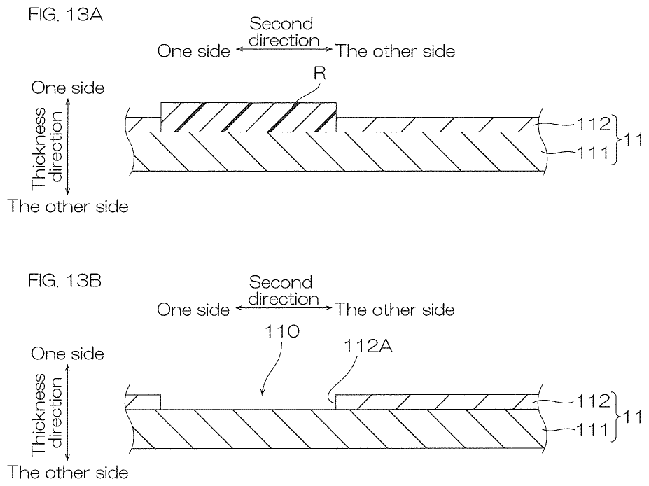

(1) The method of producing the wiring circuit board 10 may not include a penetrating hole forming step (a concave portion forming step). As shown in FIGS. 13A and 13B, in the metal forming step, a second metal layer 112 having a penetrating hole 112A may be formed on the first metal layer 111.

Specifically, as shown in FIG. 13A, in the metal layer forming step, for example, a second metal layer 112 is formed on a one-side surface of the first metal layer 111 in the thickness direction by electrolytic plating while the portion where a penetrating hole 112A (concave portion 110) is to be formed is covered with a plating resist R.

Thereafter, as shown in FIG. 13B, the plated resist R is released.

According to this modified example, by forming a second metal layer 112 having a penetrating hole 112A on the first metal layer 111, a metal layer 11 having a concave portion 110 can easily be formed.

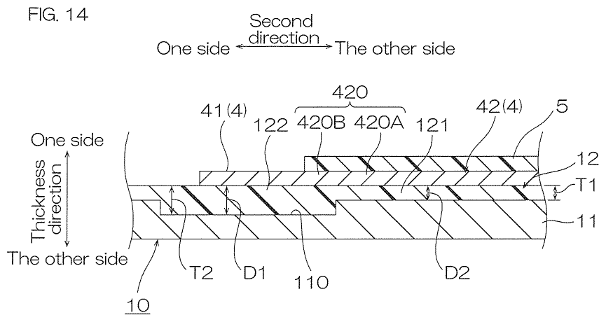

(2) As shown in FIG. 14, the metal layer 11 may not have a second metal layer 112. The metal layer 11 may be one layer made of the same material as that of the first metal layer 111.

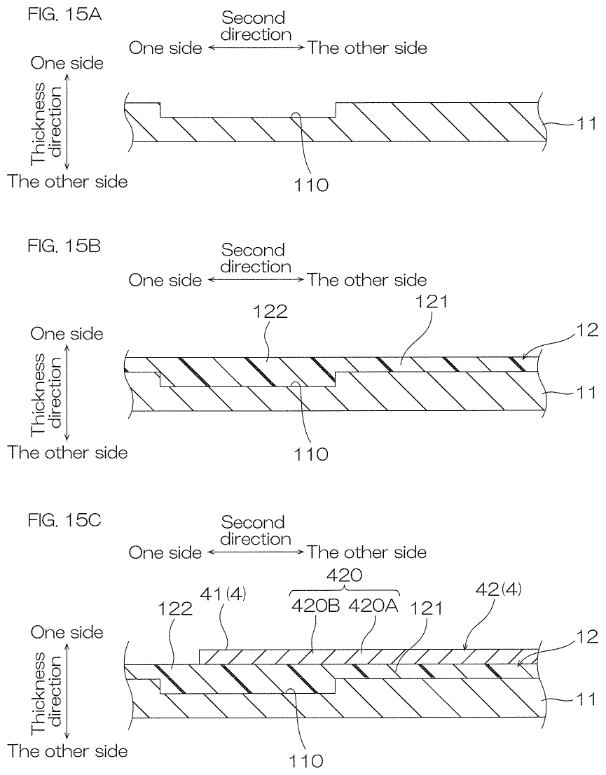

In this case, as shown in FIG. 15A, in the concave portion forming step, the metal layer 11 is etched to form a concave portion 110 in the metal layer 11. Next, as shown in FIG. 15B, in the base insulating layer forming step, a base insulating layer 12 is formed on the metal layer 11 so that the base insulating layer 12 is filled in the concave portion 110. Next, as shown in FIG. 15C, in the patterning step, a circuit pattern 4 is formed on the base insulating layers 12. Next, as shown in FIG. 14, in the cover insulating layer forming step, a cover insulating layer 5 is formed on the base insulating layer 12.

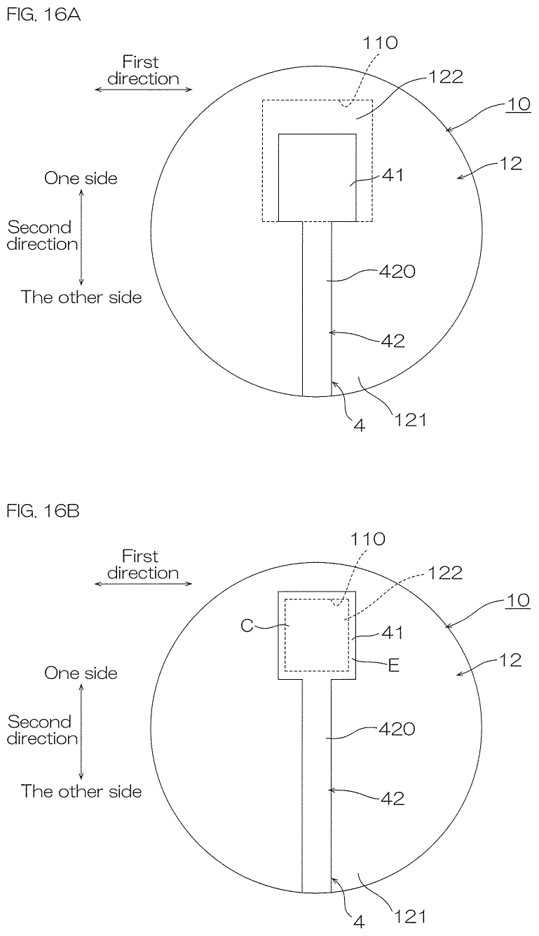

(3) As shown in FIG. 16A, the whole of the connecting portion 420 may be disposed on the first portion 121. In this case, the distance D1 between the whole of the terminal 41 and the metal layer 11 is longer than the distance D2 between the whole of the connecting portion 420 and the metal layer 11.

Therefore, the difference in impedance between the whole of the terminal 41 and the whole of the connecting portion 420 can be reduced.

As a result, the difference in impedance between the terminal 41 and the wire 42 can further be reduced.

(4) Also in the second embodiment, in the same manner as the first embodiment described above, a portion of the terminal 41 may be disposed on the first portion 121 together with the connecting portion 420. Specifically, as shown in FIG. 16B, the second portion 122 may be smaller than the terminal 41, and the peripheral edge portion E of the terminal 41 may be disposed on the first portion 121 together with the connecting portion 420. That is, one end portion of the terminal 41 in the first direction, the other end portion of the terminal 41 in the first direction, one end portion of the terminal 41 in the second direction, and the other end portion of the terminal 41 in the second direction may be disposed on the first portion 121. The central portion C of the terminal 41 is disposed on the second portion 122. The central portion C is a central portion of the terminal 41 in the first direction and a central portion of the terminal 41 in the second direction.

In this case, the area of the second portion 122 is, for example, 30% or more, preferably 50% or more, and more preferably 80% or more of the area of the terminal 41.

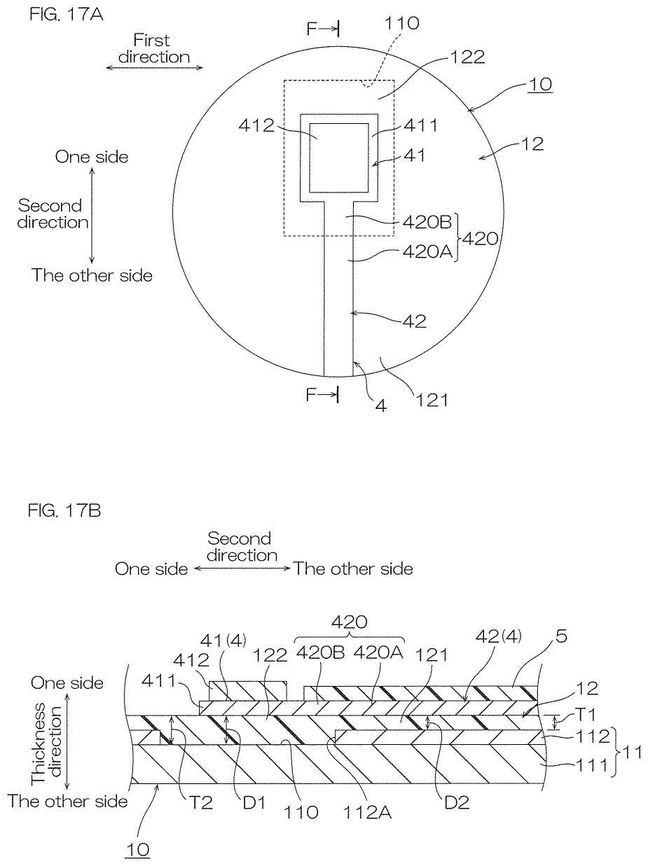

(5) Also in the second embodiment, in the same manner as the first embodiment described above, the terminal 41 may have a plurality of conductor layers. Specifically, as shown in FIGS. 17A and FIG. 17B, the terminal 41 may include a first conductor layer 411 and a second conductor layer 412. At least a portion of the first conductor layer 411 is disposed on the second portion 122 of the base insulating layer 12. The connecting portion 420 is connected to the first conductor layer 411. In this modified example, the whole of the first conductor layer 411 is disposed on the second portion 122 of the base insulating layer 12. A portion of the first conductor layer 411 may be disposed on the first portion 121 together with the connecting portion 420. The second conductor layer 412 is disposed on the first conductor layer 411.

(6) Also in modified examples (1) to (5) described above, in the same manner as the second embodiment described above, the difference in impedance between the terminal 41 and the wire 42 can be reduced without forming an opening in the metal layer 11.

While the illustrative embodiments of the present invention are provided in the above description, such is for illustrative purpose only and it is not to be construed as limiting the scope of the present invention. Modified example and variation of the present invention that will be obvious to those skilled in the art is to be covered by the following claims.

### INDUSTRIAL APPLICABILITY

The wiring circuit board of the present invention can be used for connecting electronic components. The method for producing the wiring circuit board of the present invention can be used for producing wiring circuit boards.

### DESCRIPTION OF REFERENCE NUMERALS

1 Wiring circuit board
2 Metal layer
21 First metal layer
22 Second metal layer
3 Base insulating layer
31 First portion
32 Second portion
4 Circuit pattern
41 Terminal
42 Wire
420 Connecting portion
420A Portion of connecting portion
321 First layer of second portion
322 Second layer of second portion
10 Wiring circuit board
11 Metal layer
110 Concave portion
111 First metal layer
112 Second metal layer
112A Penetrating hole
12 Base insulating layer
D1 Distance between terminal and metal layer
D2 Distance between connecting portion and metal layer
W1 Width of terminal
W2 Width of connecting portion

1. A wiring circuit board comprising:
a metal layer;
a circuit pattern having a terminal and a wire connected to the terminal; and
an insulating layer disposed between the metal layer and the circuit pattern in a thickness direction of the metal layer,
wherein the wire has a connecting portion connected to the terminal,
wherein a width of the terminal is larger than a width of the connecting portion, and
wherein in the thickness direction, a distance between at least a portion of the terminal and the metal layer is longer than a distance between at least a portion of the connecting portion and the metal layer.

2. The wiring circuit board according to claim 1,
wherein a distance between a whole of the terminal and the metal layer is longer than the distance between at least the portion of the connecting portion and the metal layer.

3. The wiring circuit board according to claim 1,
wherein the distance between the whole of the terminal and the metal layer is longer than a distance between a whole of the connecting portion and the metal layer.

4. The wiring circuit board according to claim 1,
wherein the insulating layer includes:
a first portion having a first thickness, and
a second portion having a second thickness thicker than the first thickness, wherein at least the portion of the connecting portion is disposed on the first portion, and wherein at least the portion of the terminal is disposed on the second portion.

5. The wiring circuit board according to claim 4,
wherein the whole of the terminal is disposed on the second portion.

6. The wiring circuit board according to claim 4,
wherein the whole of the connecting portion is disposed on the first portion.

7. The wiring circuit board according to claim 4,
wherein the second portion includes:
a first layer unified with the first portion, and
a second layer disposed on the first layer.

8. The wiring circuit board according to claim 4,
wherein a whole of the second portion is unified with the first portion.

9. The wiring circuit board according to claim 1,
wherein the metal layer includes:
a first metal layer, and
a second metal layer disposed between the first metal layer and the insulating layer in the thickness direction.

10. The wiring circuit board according to claim 9,
wherein the second metal layer includes:
a penetrating hole overlapping the terminal in the thickness direction.

11. The wiring circuit board according to claim 1,
wherein the metal layer includes:
a concave portion overlapping the terminal in the thickness direction, the concave portion being recessed in a direction away from the terminal in the thickness direction.

12. A method of producing the wiring circuit board according to claim 7, the method comprising:
a first insulating layer forming step of forming the first portion and the first layer of the second portion on the metal layer;
a second insulating layer forming step of forming the second layer of the second portion on the first layer; and
a patterning step of forming the circuit pattern on the insulating layer.

13. A method of producing the wiring circuit board according to claim 8, the method comprising:
an insulating layer forming step of forming the insulating layer on the metal layer; and
a patterning step of forming the circuit pattern on the insulating layer,
wherein in the insulating layer forming step, the first portion and the second portion are formed in the insulating layer by gradation exposure or etching.

14. A method of producing the wiring circuit board according to claim 10, the method comprising:
a metal layer forming step of forming the second metal layer having the penetrating bole on the first metal layer;
an insulating layer forming step of forming the insulating layer on the second metal layer so that the insulating layer is filled in the penetrating hole; and
a patterning step of forming the circuit pattern on the insulating layer.

15. A method of producing the wiring circuit board according to claim 10, the method comprising:
a metal layer forming step of forming the second metal layer on the first metal layer;
a penetrating hole forming step of etching the second metal layer to form the penetrating hole in the second metal layer;
an insulating layer forming step of forming the insulating layer on the second metal layer so that the insulating layer is filled in the penetrating hole; and
a patterning step of forming the circuit pattern on the insulating layer.

16. A method of producing the wiring circuit board according to claim 11, the method comprising:
a concave portion forming step of etching the metal layer to form the concave portion in the metal layer;
an insulating layer forming step of forming the insulating layer on the metal layer so that the insulating layer is filled in the concave portion; and
a patterning step of forming the circuit pattern on the insulating layer.
